(19) United States
(12) Patent Application Publication
(10) Pub. No.: US 2023/0142030 A1
(43) Pub. Date: May 11, 2023

(54) LIQUID METAL COMPOSITES CONTAINING ORGANIC ADDITIVE AS THERMAL INTERFACE MATERIALS, AND METHODS OF THEIR USE

(71) Applicant: INDIUM CORPORATION, Utica, NY (US)

(72) Inventor: Guangyu Fan, Deerfield, NY (US)

(21) Appl. No.: 17/982,306

(22) Filed: Nov. 7, 2022

Related U.S. Application Data
(60) Provisional application No. 63/276,496, filed on Nov. 5, 2021.

(51) Int. Cl. H01L 23/473; H01L 23/373; C22C 28/00

(52) U.S. Cl. CPC H01L 23/473; H01L 23/3736; H01L 23/3737; C22C 28/00

(57) ABSTRACT

Some implementations of the disclosure are directed to liquid metal composites that can be used as thermal interface materials. In one implementation, a liquid metal composite configured to be applied as a thermal interface material between electronic components, includes: 90 wt % to 99.9 wt % of a liquid metal or liquid metal alloy; and 0.1 wt % to 10 wt % of at least one organic additive comprising an organic compound to prevent oxidation of the liquid metal or liquid metal alloy during application of the liquid metal composite on a surface of an electronic component.

### CROSS-REFERENCE TO RELATED APPLICATIONS

This application claims priority to U.S. Provisional Patent Application No. 63/276,496, titled “LIQUID METAL COMPOSITES CONTAINING ORGANIC ADDITIVE AS THERMAL INTERFACE MATERIALS, AND METHODS OF THEIR USE” filed Nov. 5, 2021, which is incorporated herein by reference in its entirety.

### DESCRIPTION OF THE RELATED ART

Heat dissipation is a key factor in the longevity and reliability of semiconductor and power devices. To improve thermal performance, electronic assemblies may provide thermal management via a thermal interface material (TIM) that minimizes thermal resistance between a heat generating device/source (e.g., microprocessor) and a heat transferring device.

TIMs that have been widely used in electronic devices include thermal greases or pastes, pads, phase-changing materials, and adhesives. Most of these TIMs are polymer-based composites with metal or ceramic conductive particle fillers. For example, thermal grease is a commonly used TIM with thermal contact resistances typically in the range of 0.2 to 1.0 cm² K/W. The thermal contact resistance can be reduced to 0.053 cm² K/W by mixing polyethylene glycol with boron nitride. However, there are drawbacks to using thermal greases as TIMs. Greases are messy and challenging to apply and rework, and have reliability issues relating to pump out, phase separations, and dry-out. For example, the powering up and down of electronic devices causes a relative motion between the die and the heat-spreader due to their different coefficients of thermal expansion, which can tend to “pump” out the thermal grease from the interface gap. As such, although thermal greases may provide good thermal performance upon installation, upon extended use and over time, these greases can degrade, resulting in higher thermal resistance at the interface. This limits the use of grease as an efficient TIM over an electronic device's nominal lifespan of operation.

Solder is another type of TIM that has been widely used due to the higher thermal conductivity and the low contact thermal resistance (e.g., below 0.05 cm² K/W) of some solders. For example, the thermal resistance of Sn—Bi solder paste is less than 0.05 cm² K/W. It also has good reliability, which would potentially make it a promising TIM candidate for power electronics applications. However, Sn—Bi solder paste has poor rework ability, and it requires high processing temperatures that could cause void formation and thermal stress evolving into the electronic components.

As such, with the growth of faster, more powerful devices, there is a need for improved TIMs.

### BRIEF SUMMARY OF THE DISCLOSURE

Some implementations of the disclosure are directed to liquid metal composites that can be used as thermal interface materials. The liquid metal composite includes a liquid metal or liquid metal alloy, and one or more organic additives.

In one embodiment, a liquid metal composite is configured to be applied as a thermal interface material between electronic components, the liquid metal composite comprising: 90 wt % to 99.9 wt % of a liquid metal or liquid metal alloy; and 0.1 wt % to 10 wt % of at least one organic additive comprising an organic compound to prevent oxidation of the liquid metal or liquid metal alloy during application of the liquid metal composite on a surface of an electronic component. In some implementations, the liquid metal composite consists essentially of 90 wt % to 99.9 wt % of the liquid metal or liquid metal alloy; and 0.1 wt % to 10 wt % of the at least one organic additive. In some implementations, the liquid metal composite consists of 90 wt % to 99.9 wt % of the liquid metal or liquid metal alloy; and 0.1 wt % to 10 wt % of the at least one organic additive.

In some implementations, the liquid metal or liquid metal alloy is gallium or a gallium alloy. In some implementations, the liquid metal or liquid metal alloy is the gallium alloy, the gallium alloy being GaIn, GaSn, GaInSn, or GaInSnZn.

In some implementations, the gallium alloy is GaInSn and the organic compound comprises methyl ethyl ketone (MEK). In some implementations, the gallium alloy is GaInSn and the organic compound comprises methoxyperfluorobutane (MPFB). In some implementations, the gallium alloy is GaInSn and the organic compound comprises isopropanol (IPA). In some implementations, the gallium alloy is GaInSn and the organic compound comprises ethanol.

In some implementations, the organic compound has a strong affinity to gallium oxide.

In some implementations, the organic compound includes ketone, aldehyde, aliphatic alcohol, aliphatic ether, a glycol derivative, or short chain aliphatic ester containing carbon C2 to C9 and aliphatic amines.

In some implementations, the organic compound includes ketone, aldehyde, aliphatic alcohol, aliphatic ether, or a glycol derivative.

In some implementations, the at least one organic additive further comprises an oligomer.

In some implementations, the oligomer includes an ethylene glycol derivative or propylene glycol derivative.

In some implementations, the molecular weight of the oligomer is from 400 to 2000 g/mol.

In some implementations, the oligomer includes polyethylene glycol, polypropylene glycol, or polypropylene oxide.

In some implementations, the oligomer has a viscosity from 100 to 10,000 centipoise.

In some implementations, the liquid metal composite comprises 90 wt % to 99.9 wt % of the gallium alloy, and the gallium alloy comprises gallium and indium.

In some implementations, the organic compound comprises MEK, MPFB, IPA, or ethanol.

In some implementations, the gallium alloy comprises: 75 wt % to 80 wt % Ga, and 20 wt % to 25 wt % In; or 64 wt % to 69 wt % Ga, 19 wt % to 22 wt % In, and 10 wt % to 16 wt % Sn.

In some implementations, the gallium alloy is 66.5Ga20.5In13.0Sn or 78.6Ga21.4In.

In some implementations, the liquid metal composite comprises 0.1 wt % to 5 wt % of the at least one organic additive. For example, the liquid metal composite can comprise 0.1 wt % to 1 wt % of the at least one organic additive, 1 wt % to 2 wt % of the at least one organic additive, 2 wt % to 3 wt % of the at least one organic additive, 3 wt % to 4 wt % of the at least one organic additive, and/or 4 wt % to 5 wt % of the at least one organic additive.

In some implementations, the liquid metal composite consists of: 95 wt % to 99.9 wt % of the liquid metal or liquid metal alloy; and 0.1 wt % to 5 wt % of the least one organic additive.

In some implementations, the liquid metal composite has a molecular weight from 200 to 5,000 g/mol, or a thermal conductivity of greater than 20 W/mK.

In some implementations, the thermal conductivity of the liquid metal composite at room temperature is substantially the same as the thermal conductivity of the liquid metal or liquid metal alloy at room temperature without the at least one organic additive, before the liquid metal or liquid metal alloy oxidizes.

In some implementations, the liquid metal composite is dispensable or jettable with a controllable thickness or deposit amount.

In one embodiment, an assembly comprises: a heat generating device; a heat transferring device; and a thermal interface between surfaces of the heat generating device and heat transferring device, wherein the thermal interface is formed by applying a liquid metal composite comprising 90 wt % to 99.9 wt % of a liquid metal or liquid metal alloy; and 0.1 wt % to 10 wt % of at least one organic additive comprising an organic compound to prevent oxidation of the liquid metal or liquid metal alloy during application of the liquid metal composite.

In one embodiment, a method comprises: applying a liquid metal composite between a heat generating device and a heat transferring device to form an assembly having the liquid metal composite in touching relation with a surface of the heat generating device, and in touching relation with a surface of the heat transferring device, the liquid metal composite comprising 90 wt % to 99.9 wt % of a liquid metal or liquid metal alloy; and 0.1 wt % to 10 wt % of at least one organic additive comprising an organic compound to prevent oxidation of the liquid metal or liquid metal alloy during application of the liquid metal composite; and processing the assembly to form a thermal interface from the liquid metal composite, the thermal interface configured to transfer heat from the heat generating device to the heat transferring device.

In some implementations, the heat generating device is a semiconductor die, and the heat transferring device is a semiconductor package lid.

In some implementations, the heat generating device is a semiconductor die, and the heat transferring device is a heat sink.

In some implementations, applying the liquid metal composite between the heat generating device and the heat transferring device, comprises: dispensing, or jetting the liquid metal composite onto the surface of the heat generative device or the surface of the heat transferring device.

Other features and aspects of the disclosed technology will become apparent from the following detailed description, taken in conjunction with the accompanying drawings, which illustrate, by way of example, the features in accordance with implementations of the disclosed technology. The summary is not intended to limit the scope of any inventions described herein, which are defined by the claims and equivalents.

It should be appreciated that all combinations of the foregoing concepts (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein.

### BRIEF DESCRIPTION OF THE DRAWINGS

The present disclosure, in accordance with one or more implementations, is described in detail with reference to the following figures. The figures are provided for purposes of illustration only and merely depict example implementations. Furthermore, it should be noted that for clarity and ease of illustration, the elements in the figures have not necessarily been drawn to scale.

FIG. 1 shows a semiconductor assembly including a TIM formed from a liquid metal composite in accordance with some implementations of the disclosure.

FIG. 2 shows another semiconductor assembly including TIMs formed from liquid metal composites in accordance with some implementations of the disclosure.

FIG. 3A shows linear plots depicting the results of a thixotropic loop test by a parallel plate viscometer showing the effect of shear rate and time on the viscosity of each of a liquid metal composite and a liquid metal.

FIG. 3B shows log plots depicting the results of a thixotropic loop test by a parallel plate viscometer showing the effect of shear rate and time on the viscosity of each of a liquid metal composite and a liquid metal.

FIG. 4 includes plots showing the results of a strain swing loop test, including the storage modulus and loss modulus as a function of oscillation strain, when comparing a liquid metal composite with a liquid metal.

FIG. 5A illustrates the dispensing performance of a liquid metal composite on a copper printed circuit board (PCB), the liquid metal composite being in accordance with some implementations of the disclosure.

FIG. 5B illustrates the dispensing performance of a liquid metal composite on an organic solderability preservative (OSP) FR4 coupon, the liquid metal composite being in accordance with some implementations of the disclosure.

FIG. 6A shows an assembly including liquid metal composite drops dispensed from a syringe on a copper PCB, the drops dispensed from the syringe at room temperature after the liquid metal composite was formed, and the liquid metal composite being in accordance with some implementations of the disclosure.

FIG. 6B shows an assembly when drops of the liquid metal composite of FIG. 6A were dispensed from the syringe on a copper PCB after two days of storage of the liquid metal composite in the syringe.

FIG. 6C shows an assembly when drops of the liquid metal composite of FIG. 6A were dispensed from the syringe on a copper PCB, after the syringe was frozen to −10 C and then thawed before drops were dispensed.

FIG. 6D shows an assembly when drops of the liquid metal composite of FIG. 6A were dispensed from the syringe on a copper PCB, after the syringe was frozen to −20 C then thawed three times before drops were dispensed.

FIG. 7A illustrates adhesion of drops of a liquid metal composite on a copper PCB, the drops dispensed from a syringe recently after the liquid metal composite was formed, the liquid metal composite being in accordance with some implementations of the disclosure.

FIG. 7B illustrates liquid metal composite drops of the liquid metal composite of FIG. 7A, the drops dispensed after the liquid metal composite was stored in the syringe for a week, and a glass substrate pressed against a subset of the drops.

FIG. 8A illustrates drops of a liquid metal versus drops of a liquid metal composite in accordance with some implementations of the disclosure.

FIG. 8B illustrates adhesion and wetting of the liquid metal drops and liquid metal composite drops of FIG. 8A after a glass substrate is placed over the drops.

FIG. 8C illustrates adhesion and wetting of the liquid metal drops and liquid metal composite drops of FIG. 8B after additional time passes.

FIG. 9A depicts the contact angle of a liquid metal on a bare copper substrate.

FIG. 9B depicts the contact of a liquid metal composite on a bare copper substrate, the liquid metal composite being in accordance with some implementations of the disclosure.

FIG. 10A shows a Thermogravimetric Analysis (TGA) plot of a sample of a liquid metal, the plot showing the change in weight percentage of the sample as a function of temperature.

FIG. 10B shows a TGA plot of a sample of a liquid metal composite in accordance with some implementations of the disclosure, the plot showing the change in weight percentage of the sample as a function of temperature.

FIG. 11 is a chart showing thermal aging tests over 1680 hours of two liquid metal composite samples, in accordance with some implementations of the disclosure.

The figures are not exhaustive and do not limit the disclosure to the precise form disclosed.

### DETAILED DESCRIPTION OF THE EMBODIMENTS

Recently, liquid metal and liquid metal alloys such as Ga, GaIn, GaInSn have drawn attention for potential use as TIMs because of their high heat transfer capacity, good thermal conductivity, and very low contact thermal resistance. For example, a research group recently reported low melting temperature alloys containing gallium (Ga), indium (In), bismuth (Bi) and tin (Sn) had a thermal contact resistance as low as 0.005 cm² K/W, which is much lower than that of polymer-based thermal greases. Despite liquid metal alloys having low thermal interface resistances, Ga-based TIMs have several issues, including: oxidation/corrosion, intermetallic growth, dry-out, and dewetting after the oxidation of most of Ga in the alloys that would increase interfacial thermal resistance. Various methods to mitigate these problems have been proposed. For example, the oxidation of liquid metal alloys may be minimized by a hermetic seal, and the formation of intermetallic compounds may be prevented by applying a diffusion barrier coating like a nickel layer. In one experiment, it was reported that the use of a gasket sealant could reduce the oxidation of liquid metal alloys significantly. However, Ga-based TIMs have poor wettability and adhesion to Si, Cu and other surface finish substrates based on traditional deposition processes such as printing and dispensing using surface mount equipment in the electronics industry.

Thus, there is a need for developing liquid metal alloys having good wettability and adhesion on silicon, bare copper, Ni-plated, and/or Au-plated substrates. There is also a need for developing liquid metal alloys that exhibit excellent automation process performance (i.e., dispensing and/or jetting of the liquid metal on a substrate). To this end, the disclosure is directed to TIMs formed from Ga-based liquid metals or metal alloys containing organic compounds and/or oligomers, that can be consistently dispensed or jetted, with good adhesion and wettability on silicon, bare copper, Ni-plated, and/or Au-plated substrates. For example, the TIM described herein may be dispensed or jetted on bare copper PCBs and OSP FR4 coupons.

The liquid metal composite, also referred to as a “LMO”, may be formed from a liquid metal alloy containing one or more organic compounds and/or oligomers. As further described below, the inclusion of the one or more organic compounds and/or oligomers may significantly improve the performance and characteristics of the liquid metal containing TIM. In particular, the one or more organic compounds and/or oligomers may help regulate the oxidation rate of the liquid metal alloy during processing. For example, it may minimize the oxidation of gallium in the liquid metal alloy. Additionally, it may minimize variation in the viscosity and modulus of a TIM formed between two electronic components (e.g., heat generating device and heat transferring device). Further, it may allow for consistent dispensing on bare Cu PCB, good adhesion on bare Cu PCB, good adhesion on OSP FR4 coupons, and/or good adhesion on glass. Moreover, it may provide for excellent wetting on non-metallized surfaces such as glass and silicon.

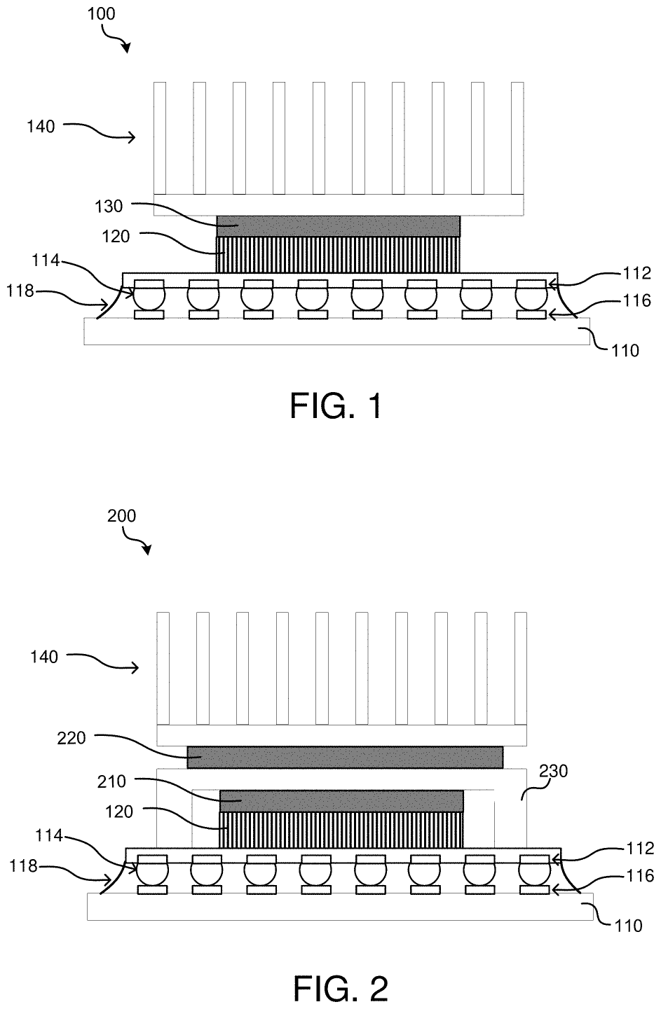

FIG. 1 shows a semiconductor assembly 100 including a TIM 130 formed from a liquid metal composite in accordance with implementations of the disclosure. In this example and other semiconductor assembly examples illustrated in the figures, the TIMs are used in a chip carrier depicted as a ball grid array (BGA) assembly. However, it should be appreciated that the TIMs may be utilized to provide a TIM in other semiconductor assemblies, chip carriers, or surface-mount packaging, including, for example, land grid arrays (LGA), pin grid arrays (PGA), and the like.

Semiconductor assembly 100 includes PCB 110, semiconductor die 120, liquid metal composite TIM 130, and heat sink 140. The semiconductor die 120 is mounted to PCB 110. Solder spheres 114 were placed on metallized pads 112 of the semiconductor die 120 and reflowed to electrically connect metallized pads 112 to the electrical connectors 116 of the PCB 110. In this manner, electrical signals may be conducted between the semiconductor die 120 and the circuit board 110 onto which the assembly is placed. 118 illustrates an underfill applied between the semiconductor die 120 and circuit board 110.

TIM 130 is configured to transfer heat generated by semiconductor die 120 to heat sink 140. In this arrangement in which TIM 130 is the thermal interface material between the semiconductor die 120 and heat sink 140, TIM 130 may be referred to as a TIM0 thermal interface material.

As further discussed below, TIM 130 may be formed from a liquid metal composite comprising 90 wt % to 99 wt % of a liquid metal or liquid metal alloy, and 1 wt % to 10 wt % of one or more organic compounds and/or oligomers. The organic compound(s) and/or oligomer(s) may be mixed with the liquid metal(s) or liquid metal alloy(s) to form the liquid metal composite. The formed liquid metal composite may provide strong thermal performance, comparable to that of the liquid metal or liquid metal alloys. In some implementations, the formed liquid metal composite has a molecular weight with a range from 200 to 5,000 g/mol.

FIG. 2 shows a semiconductor assembly 200 including a liquid metal composite TIM 210 and liquid metal composite TIM 220 in accordance with implementations of the disclosure. In this implementation, semiconductor package lid or heat spreader 230 is configured to transfer energy as heat from die 120, via TIM 210, to heat sink 140, via TIM 220.

TIM 210 is configured to transfer heat generated by semiconductor die 120 to lid 230. In this arrangement in which TIM 210 is the thermal interface material between the semiconductor die 120 and lid 230, TIM 210 may be referred to as a TIM1 thermal interface material.

TIM 220 is configured to transfer heat from lid 230 to heat sink 140. In this arrangement in which TIM 220 is the thermal interface material between the semiconductor package lid 230 and heat sink 140, TIM 220 may be referred to as a TIM2 thermal interface material.

The composition of each of TIM 210 and TIM 220 may be similar to that of TIM 130 described above, and further elaborated on below.

There are various methods that can be employed to apply the liquid metal composite to the device thermal stack up to form TIM 130, TIM 210, or TIM 220. The liquid metal composite can be scrubbed, dispensed, or jetted onto the surface(s) of the heat spreader/cold plate or heat sink 140, semiconductor package lid 230, and/or semiconductor die backside 120. For example, it may be dispensed on a surface over die 120 or lid 230. Advantageously, the liquid metal composite described herein may be dispensable or jettable using a standard dispenser and/or jetting machine or system with controllable thickness or deposit amount such as a SPEEDLINE dispenser, CAMELOT PRODIGY C2MI and MUSASHI CYBERJET 2 jetting machine. In some cases, a dam or sealant may be used to confine the liquid metal alloy between components. For TIM 1 applications, the assembly packaging may include an adhesive bonding lid or other suitable bonding mechanism. For TIM 2 or TIM 0 applications, the heat sink may be fastened to the assembly by bolts or using some other suitable bonding mechanism.

The liquid metal composites described herein may be in the liquid state at room temperature (e.g., below 30° C.), and after applying as TIM (TIM1, TIM2 or TIM0) between heat source and heat sink, have an operational temperature range from −40° C. to 200° C., where the operational temperature range refers to a temperature range in which the TIM remains stable and functions during operation of the electronic assembly.

The liquid metal or liquid metal alloy of the liquid metal composite may include gallium; gallium alloys; indium; indium alloys; a combination of indium and gallium; a combination of gallium, indium, and tin; a combination of gallium indium, tin, and zinc; mixtures thereof; or other suitable liquid metals or metal alloys; or liquid metal and liquid metal alloys containing low content of metal particles such as Ag, Cu, Cr and Ni etc. For example, it may include a gallium alloy such as GaIn, GaSn, GaInSn, or GaInSnZn, and the gallium alloy may be eutectic. The liquid metal or liquid metal alloy has a low melting temperature below 30° C. or room temperature.

The one or more organic compounds of the liquid metal composite may have thermal properties that are the same or similar to the primary liquid metal/alloy used in the composites. The thermal resistance and conductivity of the liquid metal composite may have similar values as those of the liquid metal and alloy, after a volatile organic compound like MEK is removed during dispensing or jetting the LMO onto components. In implementations where at least one oligomer is used, the oligomer may be helpful to enhancing the thermal conductivity due to its flowability and conductivity.

Additionally, the organic compound may have a strong affinity to an oxide of the liquid metal or liquid metal alloy that is produced during processing of the TIM. In particular, the organic compound may have a strong affinity to gallium oxide produced by the oxidation of gallium during application of the liquid metal TIM onto components by dispensing or jetting. It may also have an affinity to indium oxide or tin oxide generated during processing. At the same time, the organic compound may not react to the element(s) of the liquid metal or metal alloy, thereby ensuring the liquid metal composite has a suitable shelf life and thermal performance.

The organic compounds and/or oligomers described herein may provide good thermal conductivity, improve automated TIM dispensing or jetting, adhesion, improve wetting by adjusting and/or controlling the viscosity and/or modulus of the liquid metal composite, and/or preventing the liquid metal and/or liquid metal alloy from oxidizing. For example, in a specific implementation, the LMO may have a thermal conductivity of greater than 20 W/mK, greater than 25 W/mK, or even greater than 30 W/mK (e.g., about 34 W/mK).

In some implementations, the one or more organic compounds may comprise at least one of the following: ketone like methyl ethyl ketone, aldehyde like acetaldehyde, ether like butyl methyl ether, aliphatic alcohol like ethanol, IPA, or short chain aliphatic ester like ethyl acetate containing carbon C2 to C9 and aliphatic amines. These compounds may easily evaporate during the process of depositing the liquid metal composite. In a particular implementation, they comprise at least one of the following: ketone like methyl ethyl ketone, aldehyde like acetyl, ether like butyl methyl ether, aliphatic alcohol like ethanol and their derivatives. One advantage of using such organic compounds is that they may not be corrosive to the electronic components (e.g., heatsink or heat spreader) and not harm the thermal conductivity of the TIM.

The one or more oligomer additives of the liquid metal composite may be oxygenated organic materials having excellent thermal stability and high diffusivity at a broad range of temperatures. The oligomer additives may have a low viscosity. For example, the viscosity may be in the range of 100 to 10,000 centipoise.

The one or more oligomer additives may be inactive with the elements of the liquid metal or metal alloy, and, in some implementations, provide a strong affinity to oxide generated by the liquid metals. In some implementations, the one or more oligomer additives are easy to clean and do not stain the substrates or electronic components of the semiconductor assembly. In some implementations, the oligomer additives provide good thermal stability and conductivity.

In some implementations, the oligomer additives include polyethylene glycol, polypropylene glycol, or polypropylene oxide. In some implementations, the one or more oligomer additives include ethylene glycol derivatives or propylene glycol derivatives. For example, they may have a low molecular weight (e.g., from 400 to 2000 g/mol).

In some implementations, the liquid metal composite does not include any oligomers.

In some implementations, the liquid metal composite includes both an organic compound and an oligomer (e.g., a low molecular weight oligomer). In a particular implementation, the one or more organic compounds and/or one or more oligomers make up 1 wt % to 5 wt % of the liquid metal composite.

In some implementations of the disclosure, a liquid metal composite can be prepared by mixing a liquid metal alloy, such as GaIn or GaInSn (e.g., Galinstan), with a low content by wt. % of one or more organic compounds. The one or more organic compounds can include MEK, methyl butyl ketone or 2-butanone, 2-Heptanone, 2-hexanone, methyl pentyl ketone or 2-pentanone, 2-octanone, 2-nontanone; 2-decanone etc; ethanol, 1-propanol or IPA, 1-butanol or 2-butanol, 1-heptanol, 2-heptanol, 1-hexanol, 2-hexanol, 1-pentanol, 2-pentanol, 1-octanol, 2-octanol, 1-nontanol, 2-nontanol, 1-decanol, 2-decanol; perfluoro 1-octanol, and so forth; diethyl ether, methyl butyl ether, ethyl butyl ether, ethyl heptyl ether, Bis(2,2,2-trifluoroethyl) ether and so forth; methyl methanoate, methyl ethanoate, ethyl ethanoate, ethyl propanoate, isopropyl butanoate, ethyl benzoate; MPFB, ethoxyperfluorobutane, etc.

### EXPERIMENTAL RESULTS

Four example mixtures of liquid metal composites containing a liquid metal (51E) comprised of 66.5Ga20.5In13.0Sn and an organic compound were made. Each of the four liquid metal composite mixtures was made by stirring a mixture of 99 grams of 51E (66.5Ga20.5In13.0Sn) and 1 gram of the organic compound with a magnetic stir bar, at ambient temperature, for 10 minutes. The final mixture was transferred into a 10 cubic centimeter (cc) EFD syringe having a good seal. The thermal conductivity of a sample of each mixture was calculated as follows. The liquid metal composite sample was applied/dispensed between two bare Cu coupons at around room temperature. Thereafter, an LFA 447 NANOFLASH analyzer was used to measure thermal diffusivity of the applied sample. Thermal conductivity (A) of the sample was calculated based on Equation (1):

λ=α·ρ·Cₚ (1),

where λ is the thermal conductivity (W/mK) of the sample, a is the measured thermal diffusivity of the sample, p is the density (kg/m³) of the sample; and Cₚ is the specific heat capacity (J/kgK) of the sample. The calculated thermal conductivities are summarized in Table 1, below.

TABLE 1
Thermal Conductivity of Liquid Metal Composites
containing 66.5Ga20.5In13.0Sn

| | Liquid | Organic | |
|---|---|---|---|
| | Metal | Additive | Thermal |
| | (99 g) | (1 g) | Conductivity |
| Example 1 | 66.5Ga20.5In13.0Sn | MEK | 28.16 W/mK |
| Example 2 | 66.5Ga20.5In13.0Sn | IPA | 30.58 W/mK |
| Example 3 | 66.5Ga20.5In13.0Sn | Ethanol | 25.18 W/mK |
| Example 4 | 66.5Ga20.5In13.0Sn | MPFB | 28.12 W/mK |

As depicted, the calculated thermal conductivity of the liquid metal composites containing 51E and an organic additive ranged from about 25.18 W/mk to about 30.58 W/mk. This was in line (i.e., within a measurement error) with the thermal conductivity calculated for 51E without any additives (about 25 W/mk) following the above-described process. As such, the addition of the organic additive had no observed negative impact on the thermal conductivity of the liquid metal.

Dispensing performance of samples of each of Examples 1-4 was evaluated. Drops of each of the four samples were dispensed from the syringe on a Cu PCB. Some drops were dispensed when the syringe was at room temperature. Some drops were dispensed after the syringe was frozen to −10 C and then thawed. Some drops were dispensed after the syringe was frozen to −20 C and then thawed three times. In all samples it was observed that the liquid metal composite remained very stable over time and temperature changes. Additionally, in all samples it was observed that the liquid metal composite had good adhesion on the Cu PCB, and good adhesion and wetting on a glass substrate placed thereon. One advantage of being able to store the sample at a low temperature is that this can reduce the oxidation rate of the liquid metal in the composite.

Although the foregoing examples illustrate a liquid metal composite mixture containing a 66.5Ga20.5In13.0Sn liquid metal, the GaInSn liquid metal composite embodiments described herein are not necessarily limited to this precise example. For example, in some implementations the liquid metal composite can contain a liquid metal consisting of 64 wt % to 69 wt % Ga, 19 wt % to 22 wt % In, and 10 wt % to 16 wt % Sn.

Three additional example mixtures of liquid metal composites containing a liquid metal (300E) comprised of 78.6Ga21.4In and an organic compound were made. Each of the three liquid metal composite mixtures was made by stirring a mixture of 99 grams of 300E (78.6Ga21.4In) and 1 gram of the organic compound with a magnetic stir bar, at ambient temperature, for 10 minutes. The final mixture was transferred into a 10cc EFD syringe having a good seal. The thermal conductivity of a sample of each mixture was calculated as follows. The liquid metal composite sample was applied/dispensed between two bare Cu coupons at around room temperature. Thereafter, an LFA 447 NANOFLASH analyzer was used to measure thermal diffusivity of the applied sample. Thermal conductivity (λ) of the sample was calculated based on Equation (1). The calculated thermal conductivities are summarized in Table 2, below.

TABLE 2
Thermal Conductivity of Liquid Metal
Composites containing 78.6Ga21.4In

| | Liquid | Organic | |
|---|---|---|---|
| | Metal | Additive | Thermal |
| | (99 g) | (1 g) | Conductivity |
| Example 5 | 78.6Ga21.4In | MEK | 26.93 W/mK |
| Example 6 | 78.6Ga21.4In | MPFB | 25.93 W/mK |
| Example 7 | 78.6Ga21.4In | IPA | 24.25 W/mK |

As depicted, the measured thermal conductivity of the liquid metal composites containing 300E and an organic additive ranged from about 24.25 W/mk to about 26.93 W/mk. This was in line (i.e., within a measurement error) with the thermal conductivity calculated for 300E without any additives (about 30 W/mk) following the above-described process. As such, the addition of the organic additive had no observed negative impact on the thermal conductivity of the liquid metal.

Dispensing performance of samples of each of Examples 5-7 was evaluated. Drops of each of the three samples were dispensed from the syringe on a Cu PCB. Some drops were dispensed when the syringe was at room temperature. Some drops were dispensed after the syringe was frozen to −10 C and then thawed. Some drops were dispensed after the syringe was frozen to −20 C and then thawed three times. In all samples it was observed that the liquid metal composite remained very stable over time and temperature changes. Additionally, in all samples it was observed that the liquid metal composite had good adhesion on the Cu PCB, and good adhesion and wetting on a glass substrate placed thereon. One advantage of being able to store the sample at a low temperature is that this can reduce the oxidation rate of the liquid metal in the composite.

Although the foregoing examples illustrate a liquid metal composite mixture containing a 78.6Ga21.4In liquid metal, the GaIn liquid metal composite embodiments described herein are not necessarily limited to this precise example. For example, in some implementations the liquid metal composite can contain a liquid metal consisting of 75 wt % to 80 wt % Ga, and 20 wt % to 25 wt % In.

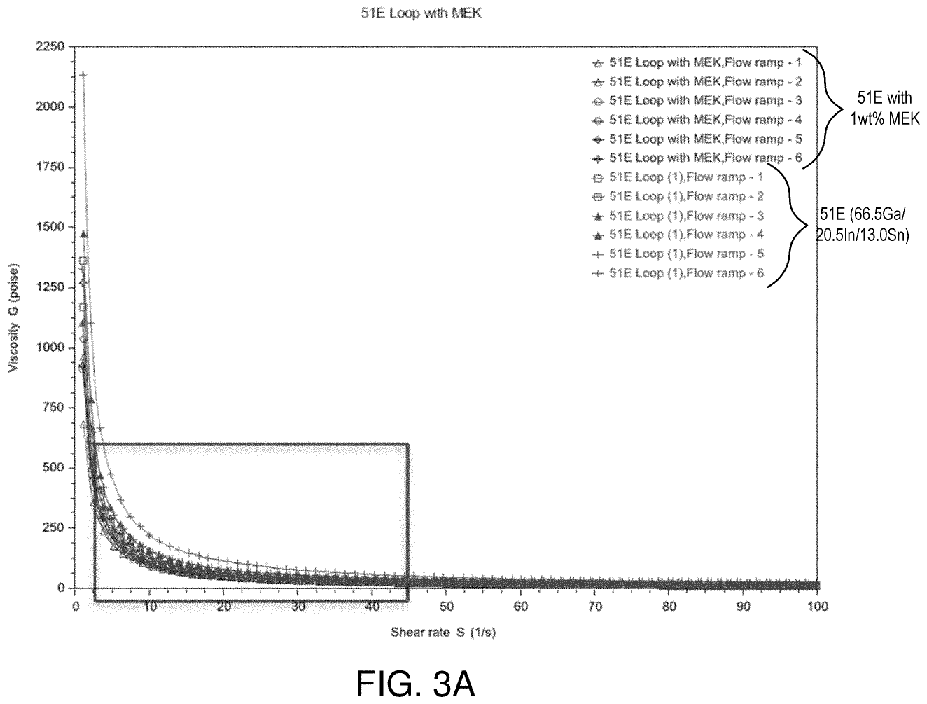

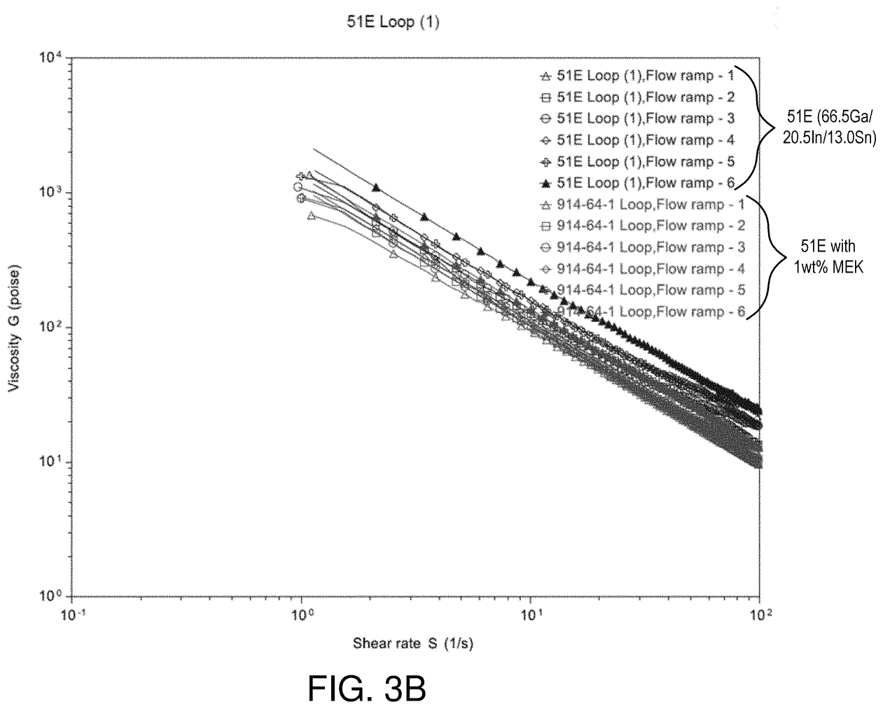

Comparative tests were conducted showing performance differences between a liquid metal composite in accordance with the disclosure and a liquid metal without any additives. Specifically, comparison tests were conducted between the liquid metal (51E) comprised of 66.5Ga20.5In13.0Sn, and a liquid metal composite (LMO51E) containing 66.5Ga20.5In13.0Sn and 1 wt % MEK. FIGS. 3A-10B depict the results.

FIGS. 3A-3B depict the results of a thixotropic loop test by a TA Instruments AR-G2 parallel plate viscometer showing the effect of shear rate and time on the viscosity of LMO51E and the liquid metal 51E. FIG. 3A shows a regular plot. FIG. 3B shows a log plot. As illustrated, with the addition of MEK, the viscosity of the composite was more stable and consistent during loop test which indicate the suppression of oxidation of Ga in liquid metal alloys (51E, 66.5Ga20.5In13.0Sn).

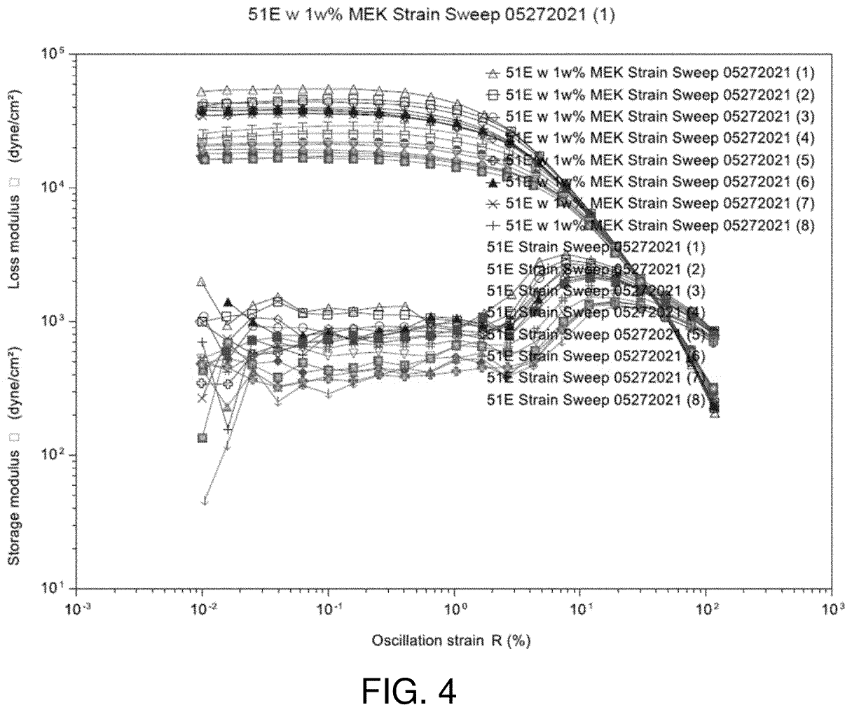

FIG. 4 illustrates MEK could significantly enhance storage (G′) and loss modulus (G″) of liquid metal alloys (51E, 66.5Ga20.5In13.0Sn), and LMO51E also shows more consistent stable modulus over strain swing loop test using a TA Instruments AR-G2 parallel plate viscometer.

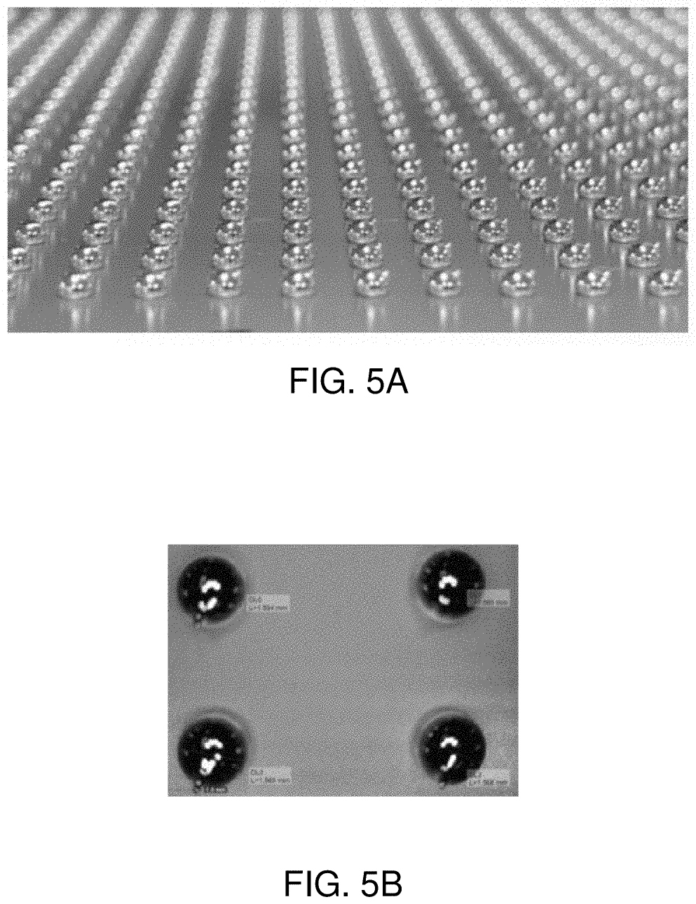

FIG. 5A-5B illustrate the dispensing performance of LMO51E on a Cu PCB (FIG. 5A) and an OSP FR4 coupon (FIG. 5B). As depicted, the dispensed drops of LMO51E were uniform in shape and size, and provided good adhesion to the substrate. Additionally, the drops were able to be dispensed using SPEEDLINE DISPENSER, CAMELOT PRODIGY C2MI, without any issues.

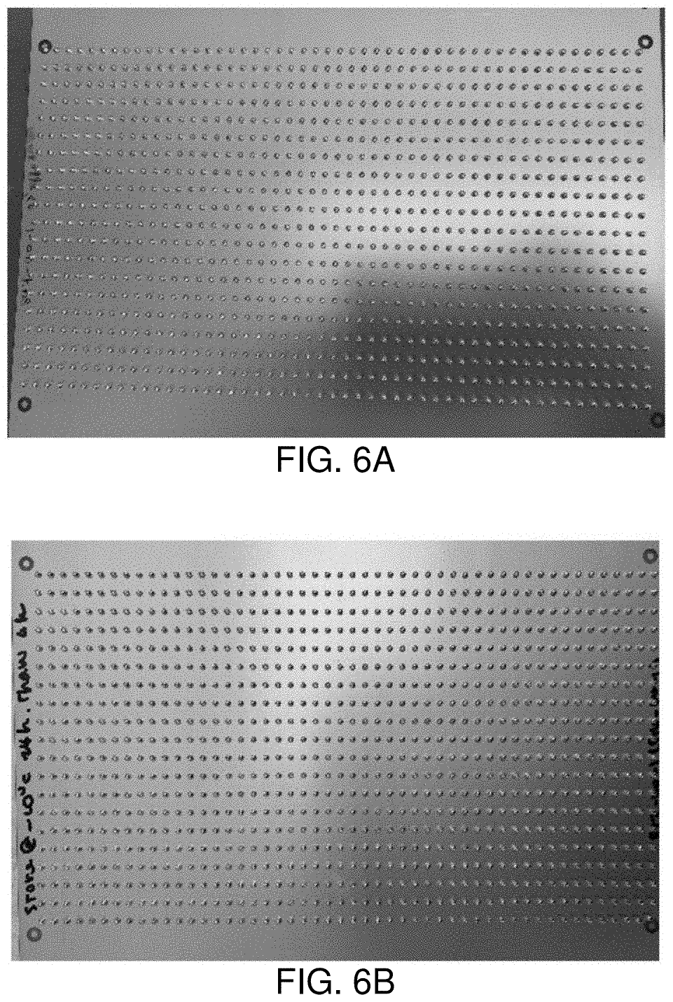

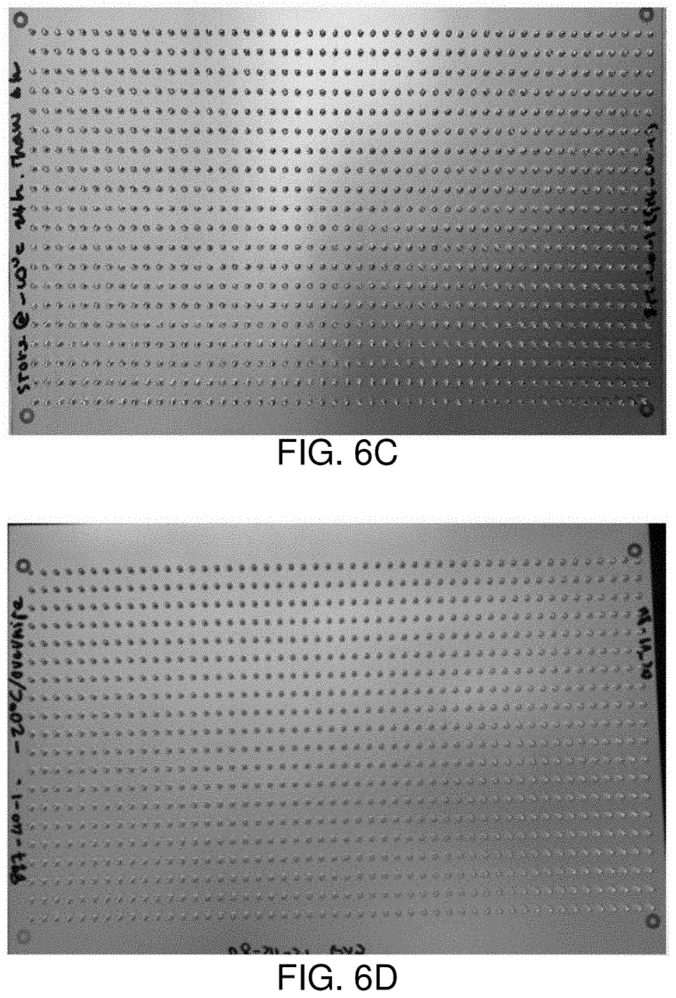

FIGS. 6A-6D show assemblies illustrating the stability over time and temperature of a LMO51E composite that had drops dispensed on a Cu PCB. FIG. 6A shows an assembly when drops were dispensed from the syringe at room temperature, after being formed. FIG. 6B shows an assembly when drops where dispensed from the syringe after two days of storage. FIG. 6C shows an assembly after the syringe was frozen to −10 C and then thawed before drops were dispensed. FIG. 6D shows an assembly after the syringe was frozen to −20 C then thawed three times before drops were dispensed. As illustrated, the liquid metal composite remained very stable over time and temperature changes.

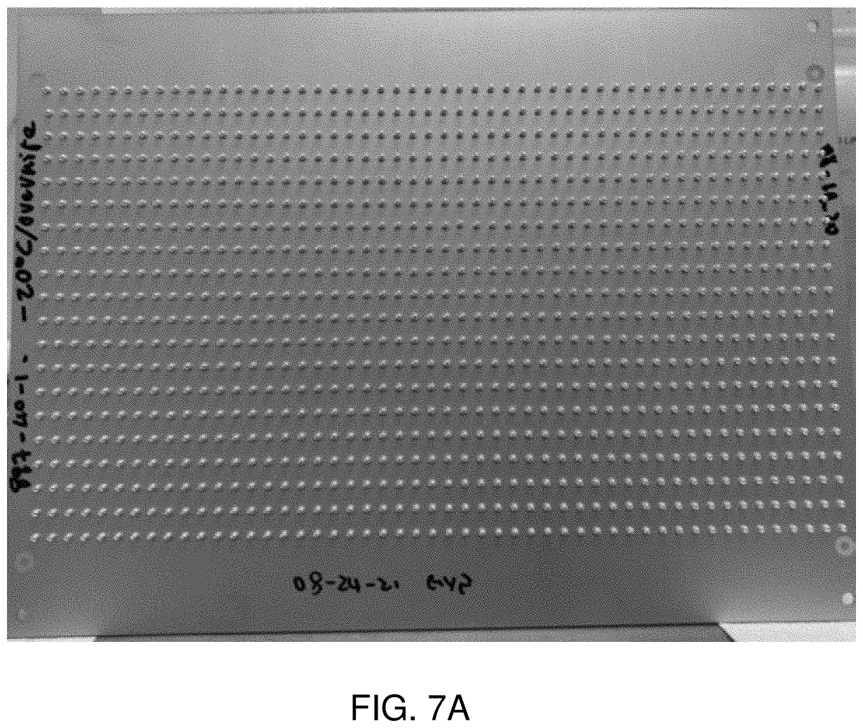

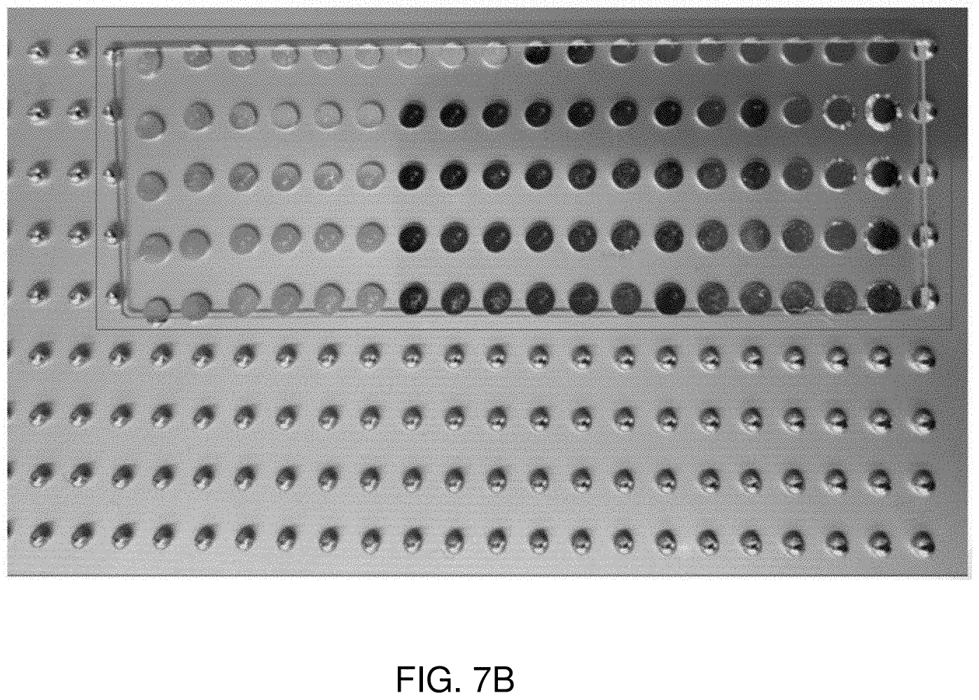

FIG. 7A illustrates adhesion of LMO51E drops on a Cu PCB, the drops dispensed from a syringe recently after the LMO51E composite was formed. As depicted, despite the vertical orientation of the Cu PCB, the drops adhered very well without sliding off. FIG. 7B illustrates drops of the LMO51E composite of FIG. 7A, the drops dispensed after the LMO51E composite was stored in the syringe for a week, and a glass substrate pressed against a subset of the drops. As depicted, the drops exhibited good adhesion to the Cu substrate and wetting to the glass substrate.

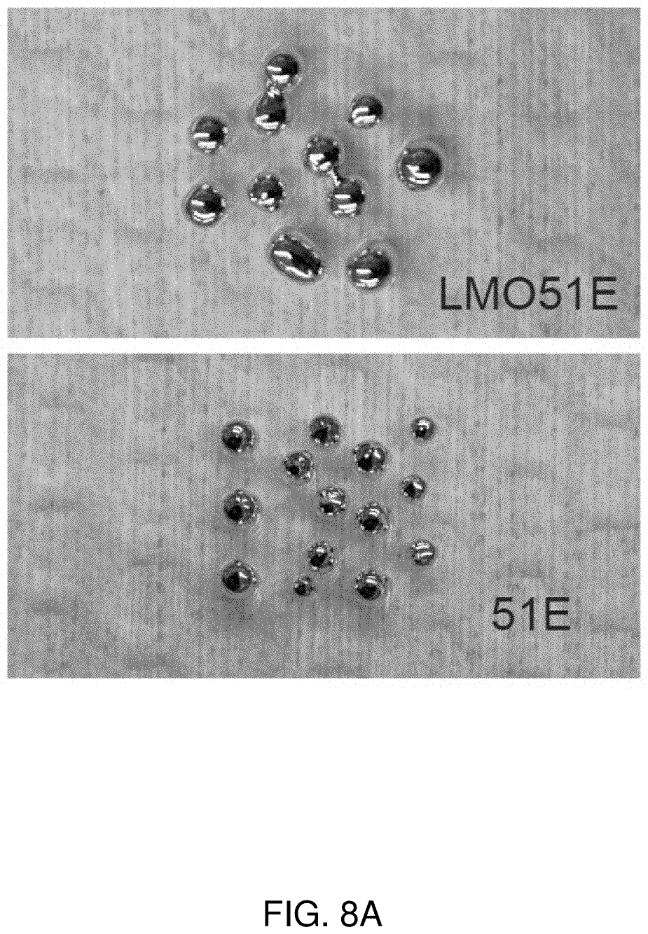

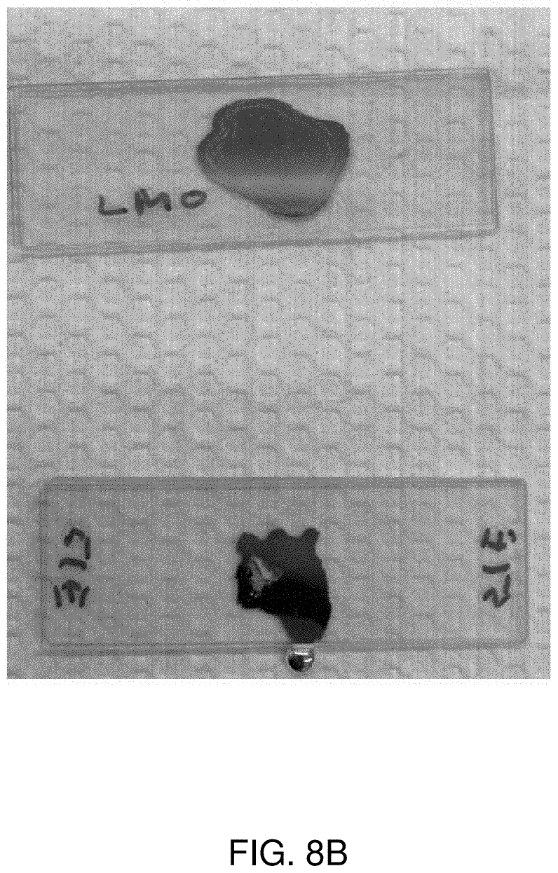

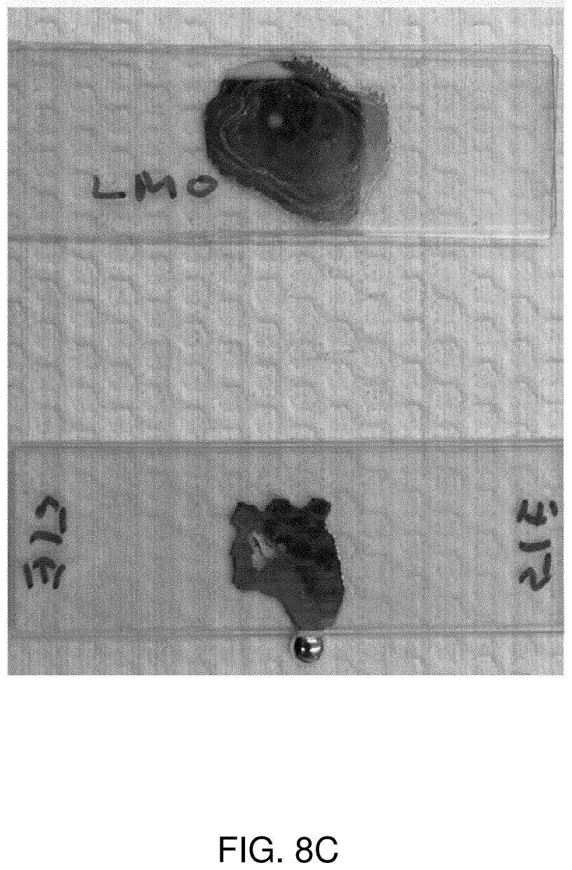

FIGS. 8A-8C illustrate adhesion and wetting of LMO51E drops versus 51E drops to a glass substrate placed over the drops. As depicted, the LMO51E drops adhered and wetted better to the glass substrate

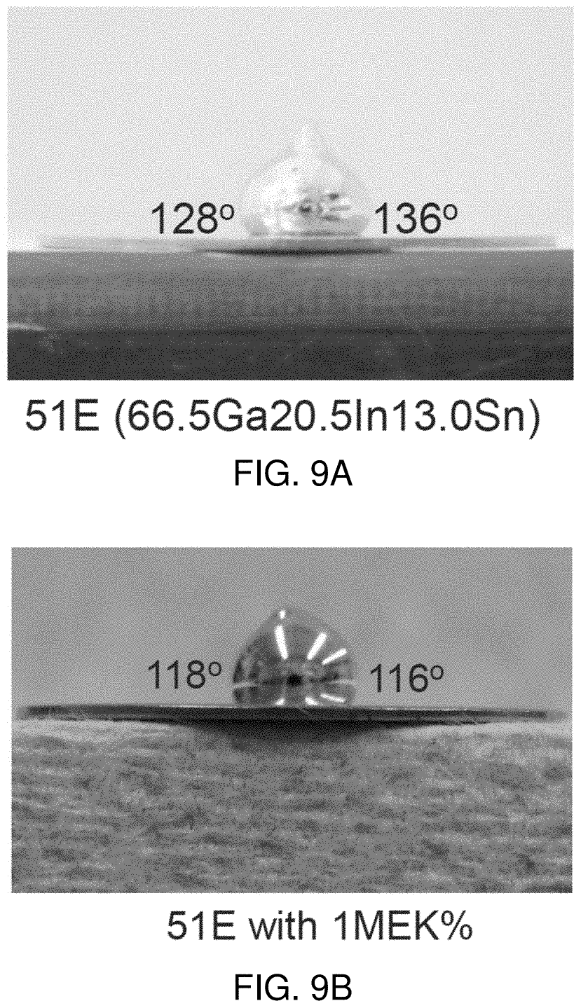

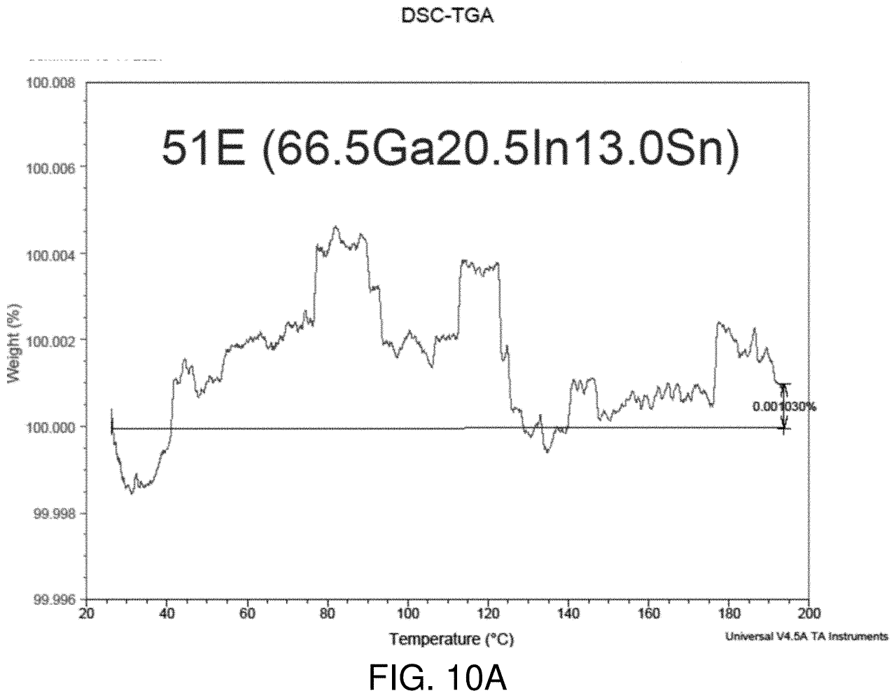

FIGS. 9A-9B depict the contact angle of a 51E drop on a bare copper substrate (FIG. 9A) versus LMO51E on the bare copper substrate (FIG. 9B). As shown, the contact angle for LMO51E is smaller, and the LMO51E composition exhibits better wettability of the liquid metal alloy on the bare copper as compared to the liquid metal alloy without MEK.

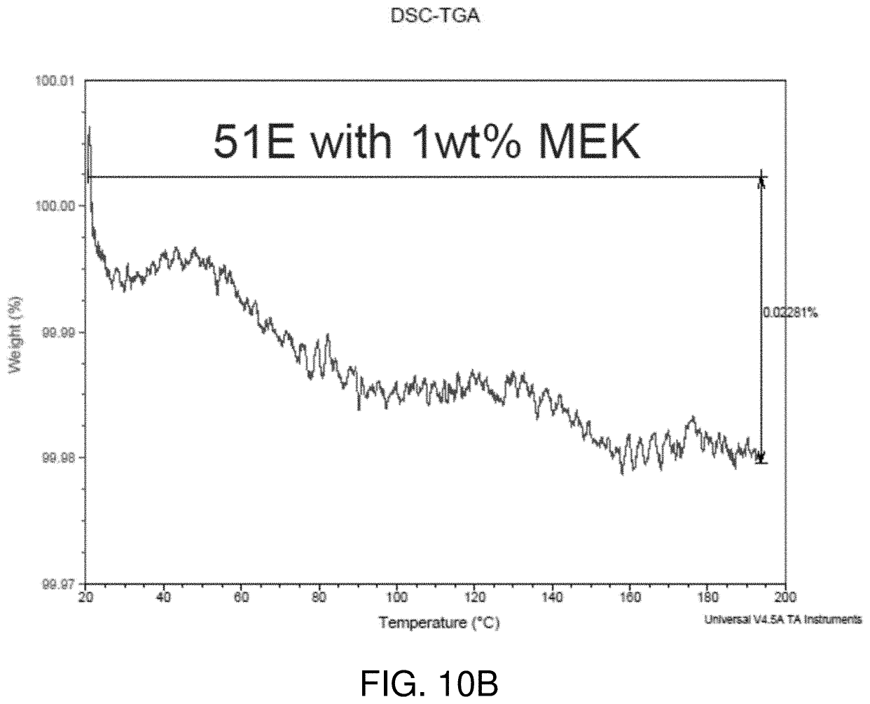

FIGS. 10A-10B show Thermogravimetric Analysis (TGA) plots of samples of the 51E liquid metal alloy (FIG. 10A) and the LMO51E liquid metal composite (FIG. 10B), showing the change in weight percentage of the sample as a function of temperature. In the case of the 51E liquid metal alloy, the oxidation of Ga causes the depicted changes of mass increase in weight. By contrast, in the case of LMO51E, the MEK compound helps suppress the oxidation of Ga.

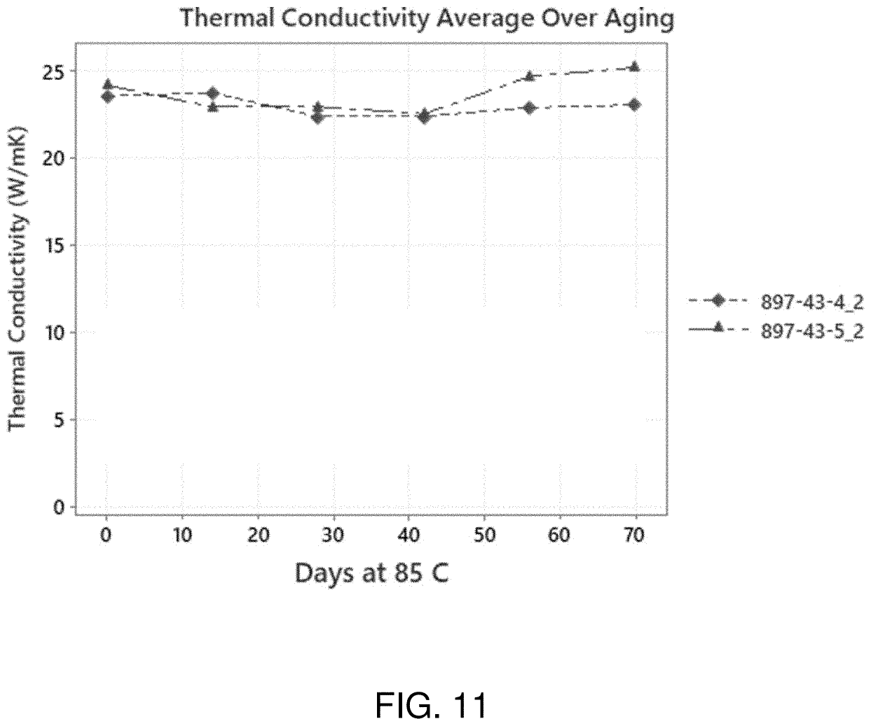

FIG. 11 is a chart showing thermal aging tests over 1680 hours of two liquid metal composite samples, in accordance with some implementations of the disclosure. As depicted, sample 897-43-4_2 has the composition of Example 2 (51E with IPA), and sample 897-43-5_2 has the composition of Example 1 (51E with MEK). The liquid metal composite sample was applied/dispensed between two bare Cu coupons to make a thermal aging test vehicle that was placed inside a box oven to conduct thermal aging tests at 85 degrees Celsius over a period of time (1680 hours). For each periodic sampling time (e.g., about every 10-15 days), the sample was removed from the oven and multiple thermal diffusivity measurements of the sample were taken using an LFA 447 NANOFLASH analyzer, and averaged. Thermal conductivity (λ) of the sample was calculated based on Equation (1). As depicted, the two liquid metal composite samples exhibited excellent long-term thermal performance after 1680 hours, the thermal conductivity remaining very stable as compared to time 0 (i.e., before commencing thermal aging).

While various embodiments of the disclosed technology have been described above, it should be understood that they have been presented by way of example only, and not of limitation. Likewise, the various diagrams may depict an example architectural or other configuration for the disclosed technology, which is done to aid in understanding the features and functionality that can be included in the disclosed technology. The disclosed technology is not restricted to the illustrated example architectures or configurations, but the desired features can be implemented using a variety of alternative architectures and configurations. Additionally, with regard to flow diagrams, operational descriptions and method claims, the order in which the steps are presented herein shall not mandate that various embodiments be implemented to perform the recited functionality in the same order unless the context dictates otherwise.

Although the disclosed technology is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the disclosed technology, whether or not such embodiments are described and whether or not such features are presented as being a part of a described embodiment. Thus, the breadth and scope of the technology disclosed herein should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

It should be appreciated that all combinations of the foregoing concepts (provided such concepts are not mutually inconsistent) are contemplated as being part of the inventive subject matter disclosed herein. In particular, all combinations of claimed subject matter appearing in this disclosure are contemplated as being part of the inventive subject matter disclosed herein.

What is claimed is:

1. A liquid metal composite configured to be applied as a thermal interface material between electronic components, the liquid metal composite comprising:
90 wt % to 99.9 wt % of a liquid metal or liquid metal alloy; and
0.1 wt % to 10 wt % of at least one organic additive comprising an organic compound to prevent oxidation of the liquid metal or liquid metal alloy during application of the liquid metal composite on a surface of an electronic component.

2. The liquid metal composite of claim 1, wherein the liquid metal or liquid metal alloy is gallium or a gallium alloy.

3. The liquid metal composite of claim 2, wherein the liquid metal or liquid metal alloy is the gallium alloy, the gallium alloy being GaIn, GaSn, GaInSn, or GaInSnZn.

4. The liquid metal composite of claim 3, wherein the gallium alloy is GaInSn and the organic compound comprises methyl ethyl ketone (MEK), methoxyperfluorobutane (MPFB), isopropanol (IPA), or ethanol.

5. The liquid metal composite of claim 2, wherein the organic compound has a strong affinity to gallium oxide.

6. The liquid metal composite of claim 2, wherein the organic compound includes ketone, aldehyde, aliphatic alcohol, aliphatic ether, a glycol derivative, or short chain aliphatic ester containing carbon C2 to C9 and aliphatic amines.

7. The liquid metal composite of claim 6, wherein the organic compound includes ketone, aldehyde, aliphatic alcohol, aliphatic ether, or a glycol derivative.

8. The liquid metal composite of claim 2, wherein the at least one organic additive further comprises an oligomer.

9. The liquid metal composite of claim 8, wherein the oligomer includes an ethylene glycol derivative or propylene glycol derivative.

10. The liquid metal composite of claim 9, wherein the molecular weight of the oligomer is from 400 to 2000 g/mol.

11. The liquid metal composite of claim 8, wherein the oligomer includes polyethylene glycol, polypropylene glycol, or polypropylene oxide.

12. The liquid metal composite of claim 8, wherein the oligomer has a viscosity from 100 to 10,000 centipoise.

13. The liquid metal composite of claim 2, wherein the liquid metal composite comprises 90 wt % to 99.9 wt % of the gallium alloy, the gallium alloy comprising gallium and indium.

14. The liquid metal composite of claim 13, wherein the organic compound comprises MEK, MPFB, IPA, or ethanol.

15. The liquid metal composite of claim 13, wherein the gallium alloy comprises:
75 wt % to 80 wt % Ga, and 20 wt % to 25 wt % In; or
64 wt % to 69 wt % Ga, 19 wt % to 22 wt % In, and 10 wt % to 16 wt % Sn.

16. The liquid metal composite of claim 15, wherein the gallium alloy is 66.5Ga20.5In13.0Sn or 78.6Ga21.4In.

17. The liquid metal composite of claim 1, comprising:
0.1 wt % to 5 wt % of the at least one organic additive.

18. The liquid metal composite of claim 17, consisting of:
95 wt % to 99.9 wt % of the liquid metal or liquid metal alloy; and
0.1 wt % to 5 wt % of the least one organic additive.

19. The liquid metal composite of claim 1, wherein the liquid metal composite has a molecular weight from 200 to 5,000 g/mol, or a thermal conductivity of greater than 20 W/mK.

20. The liquid metal composite of claim 1, wherein a thermal conductivity of the liquid metal composite at room temperature is substantially the same as a thermal conductivity of the liquid metal or liquid metal alloy at room temperature without the at least one organic additive, before the liquid metal or liquid metal alloy oxidizes.

21. The liquid metal composite of claim 1, wherein the liquid metal composite is dispensable or jettable with a controllable thickness or deposit amount.

22. An assembly, comprising:
a heat generating device;
a heat transferring device; and
a thermal interface between surfaces of the heat generating device and heat transferring device, wherein the thermal interface is formed by applying a liquid metal composite comprising 90 wt % to 99.9 wt % of a liquid metal or liquid metal alloy; and 0.1 wt % to 10 wt % of at least one organic additive comprising an organic compound to prevent oxidation of the liquid metal or liquid metal alloy during application of the liquid metal composite.

23. A method, comprising:
applying a liquid metal composite between a heat generating device and a heat transferring device to form an assembly having the liquid metal composite in touching relation with a surface of the heat generating device, and in touching relation with a surface of the heat transferring device, the liquid metal composite comprising 90 wt % to 99.9 wt % of a liquid metal or liquid metal alloy; and 0.1 wt % to 10 wt % of at least one organic additive comprising an organic compound to prevent oxidation of the liquid metal or liquid metal alloy during application of the liquid metal composite; and
processing the assembly to form a thermal interface from the liquid metal composite, the thermal interface configured to transfer heat from the heat generating device to the heat transferring device.

24. The method of claim 23, wherein:
the heat generating device is a semiconductor die, and the heat transferring device is a semiconductor package lid; or
the heat generating device is a semiconductor die, and the heat transferring device is a heat sink.

25. The method of claim 23, wherein:
applying the liquid metal composite between the heat generating device and the heat transferring device, comprises: dispensing, or jetting the liquid metal composite onto the surface of the heat generative device or the surface of the heat transferring device.
